(19) United States
(12) Patent Application Publication
(10) Pub. No.: US 2016/0343646 A1
(43) Pub. Date: Nov. 24, 2016

(54) HIGH ASPECT RATIO INTERCONNECT FOR WAFER LEVEL PACKAGE (WLP) AND INTEGRATED CIRCUIT (IC) PACKAGE

(71) Applicant: QUALCOMM Incorporated, San Diego, CA (US)

(72) Inventors: Reynante Tamunan Alvarado, San Diego, CA (US); Lizabeth Ann Keser, San Diego, CA (US); Tong Cui, San Diego, CA (US)

(21) Appl. No.: 14/836,501

(22) Filed: Aug. 26, 2015

Related U.S. Application Data
(60) Provisional application No. 62/164,960, filed on May 21, 2015.

(51) Int. Cl. H01L 23/498; H01L 21/48

(52) U.S. Cl. CPC H01L 23/49811; H01L 21/4857

(57) ABSTRACT

A package (e.g., wafer level package) that includes a die, a redistribution portion coupled to the die, a first high aspect ratio (HAR) interconnect coupled to the redistribution portion of the package, where the first high aspect ratio (HAR) interconnect comprises a width to height ratio of about at least 1:2, and a first solder interconnect coupled to the first high aspect ratio (HAR) interconnect and the redistribution portion. In some implementations, the first high aspect ratio (HAR) interconnect is a composite interconnect that includes a first conductive core and a first conductive layer that at least partially encapsulates the first conductive core. In some implementations, the first conductive layer is a diffusion barrier.

### CLAIM OF PRIORITY/CLAIM OF BENEFIT

The present application claims priority to U.S. Provisional Application No. 62/164,960 titled “High Aspect Ratio Interconnect For a Wafer Level Package and/or Integrated Device Package”, filed May 21, 2015, which is hereby expressly incorporated by reference herein.

### BACKGROUND

1. Field

Various features relate to integrated circuit (IC) packages, but more specifically to a high aspect ratio interconnect for a wafer level package and/or an integrated circuit (IC) package.

2. Background

FIG. 1 illustrates a package 100 (e.g., integrated circuit (IC) package) that includes a first die 102 and a package substrate 106. The package substrate 106 includes a dielectric layer 160 and a plurality of interconnects 162. The package substrate 106 is a laminated substrate. The plurality of interconnects 162 includes traces, pads and/or vias. The first die 102, which may be a bare die, is coupled to the package substrate 106 through a first plurality of solder balls 112. The package substrate 106 is coupled to a printed circuit board (PCB) 108 through a second plurality of solder balls 116.

Typically, solder balls have a width to height aspect ratio of about 1:1. Due to the size and aspect ratio of solder balls, the use of solder balls (e.g., solder balls 116) to couple the package 100 to the printed circuit board (PCB) 108 severely limits how many connections there can be between the package 100 and the printed circuit board (PCB) 108. Since solder balls take up so much space, the only way to increase the number of connections between the package 100 and the printed circuit board (PCB) 108 is to increase the size of the package 100, which is not ideal, as there is an ongoing need for an package with a better form factor (e.g., smaller form factor), while at the same time meeting the needs and/or requirements of mobile computing devices and/or wearable computing devices.

FIG. 2 illustrates a profile view of another package 200 (e.g., wafer level package). The package 200 includes a substrate 201, several lower metal and lower dielectric layers 202, a pad 204, a passivation layer 206, a first insulation layer 208, a first metal layer 210, a second insulation layer 212, and an under bump metallization (UBM) layer 214. The pad 204, the first metal layer 210 and the UBM layer 214 are a conductive material (e.g., copper). FIG. 2 also illustrates a solder ball 216 on the package 200. Specifically, the solder ball 216 is coupled to the UBM layer 214. The solder ball 216 has a width to height aspect ratio of about 1:1, which is not ideal for providing high density connections between the package 200 and a printed circuit board. In particular, the relatively large size of the solder ball 216 limits the pitch between solder balls, and thus limits the high density connections of the package 200.

Therefore, there is a need for a package (e.g., wafer level package) with improved connection and an improved form factor, while at the same time meeting the needs and/or requirements of mobile computing devices and/or wearable computing devices.

### SUMMARY

Various features relate to a high aspect ratio interconnect for a wafer level package and/or an integrated circuit (IC) package.

One example provides a package that includes a die, a redistribution portion coupled to the die, a first high aspect ratio (HAR) interconnect coupled to the redistribution portion of the package, where the first high aspect ratio (HAR) interconnect comprises a width to height ratio of about at least 1:2, and a first solder interconnect coupled to the first high aspect ratio (HAR) interconnect and the redistribution portion.

Another example provides a device that includes a printed circuit board (PCB) and a package coupled to the printed circuit board (PCB). The package includes a die, a redistribution portion coupled to the die, a first high aspect ratio (HAR) interconnect coupled to the redistribution portion of the package and the printed circuit board (PCB), where the first high aspect ratio (HAR) interconnect comprises a width to height ratio of about at least 1:2, and a first solder interconnect coupled to the first high aspect ratio (HAR) interconnect and the redistribution portion. The device includes a second solder interconnect coupled to the first high aspect ratio (HAR) interconnect and the printed circuit board (PCB).

Another example provides a method for fabricating a package. The method provides a die. The method forms a redistribution portion over the die. The method forms a first solder interconnect on the redistribution portion. The method uses the first solder interconnect to couple a first high aspect ratio (HAR) interconnect to the redistribution portion of the package, where the first high aspect ratio (HAR) interconnect comprises a width to height ratio of about at least 1:2.

Another example provides a package that includes a die, several solder balls coupled to the die, a package substrate coupled to the die through the several solder balls, a first high aspect ratio (HAR) interconnect coupled to the package substrate, where the first high aspect ratio (HAR) interconnect includes a width to height ratio of about at least 1:2, and a first solder interconnect coupled to the first high aspect ratio (HAR) interconnect and the package substrate.

### DRAWINGS

Various features, nature and advantages may become apparent from the detailed description set forth below when taken in conjunction with the drawings in which like reference characters identify correspondingly throughout.

FIG. 1 illustrates a profile view of a package.

FIG. 2 illustrates a profile view of another package.

FIG. 3 illustrates a profile view of an example of a package (e.g., wafer level package) comprising a high aspect ratio interconnect.

FIG. 4 illustrates a plan view of a redistribution metal layer in a package.

FIG. 5 illustrates a profile view of another example of a package (e.g., wafer level package) comprising a high aspect ratio interconnect.

FIG. 6 illustrates a plan view of a redistribution metal layer in a package.

FIG. 7 illustrates a profile view of an example of a high aspect ratio interconnect comprising a core interconnect.

FIG. 8 illustrates a plan view of an example of a high aspect ratio interconnect comprising a core interconnect.

FIG. 9 illustrates a profile view of another example of a high aspect ratio interconnect comprising a core interconnect.

FIG. 10 illustrates a plan view of another example of a high aspect ratio interconnect comprising a core interconnect.

FIG. 11 illustrates a sequence for coupling a package (e.g., wafer level package) comprising at least one high aspect ratio interconnect, to a printed circuit board (PCB).

FIG. 12 (comprising FIGS. 12A-12D) illustrates an exemplary sequence for fabricating a package (e.g., wafer level package) that includes a high aspect ratio interconnect.

FIG. 13 illustrates an exemplary flow diagram of a method for fabricating a package that includes a high aspect ratio interconnect.

FIG. 14 illustrates a profile view of an example of a wafer level package (WLP) comprising a high aspect ratio interconnect.

FIG. 15 illustrates a profile view of another example of a wafer level package (WLP) comprising a high aspect ratio interconnect.

FIG. 16 illustrates a profile view of another example of a package comprising a high aspect ratio interconnect.

FIG. 17 illustrates an exemplary sequence for fabricating a package comprising a die and a high aspect ratio interconnect.

FIG. 18 illustrates various electronic devices that may integrate a die, an integrated device, a device package, a package, an integrated circuit and/or PCB described herein.

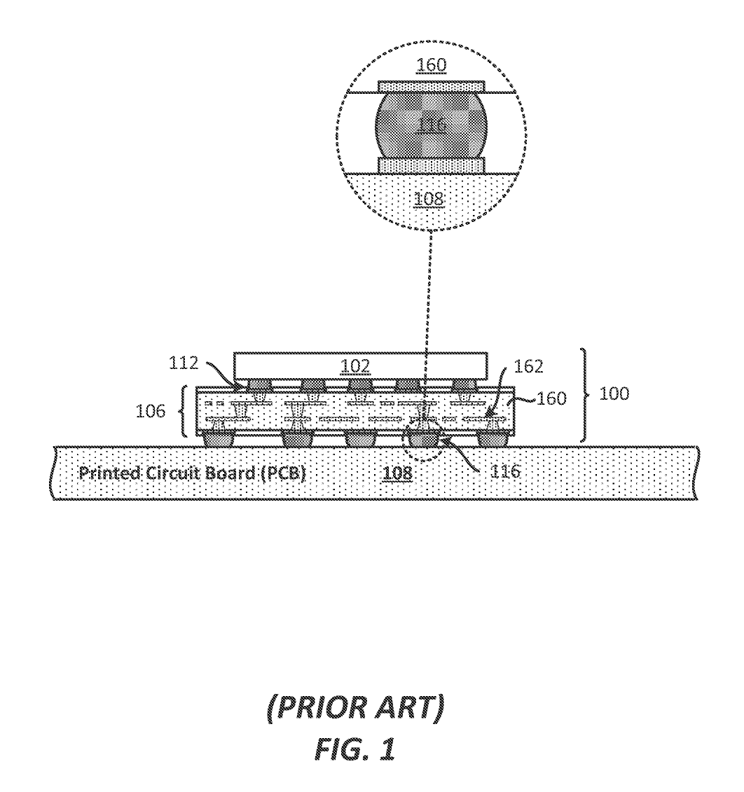

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package (e.g., wafer level package) that includes a die, a redistribution portion coupled to the die, a first high aspect ratio (HAR) interconnect coupled to the redistribution portion of the package, where the first high aspect ratio (HAR) interconnect comprises a width to height ratio of about at least 1:2. The package also includes a first solder interconnect coupled to the first high aspect ratio (HAR) interconnect and the redistribution portion. In some implementations, the first high aspect ratio (HAR) interconnect includes a first conductive core, and a first conductive layer that at least partially encapsulates the first conductive core. In some implementations, the first conductive layer is a diffusion barrier. In some implementations, the first conductive core includes a first surface, a second surface and a third surface. The first conductive layer at least partially encapsulates the first surface, the second surface and the third surface of the first conductive core.

An interconnect is an element or component of a device (e.g., integrated device, package, integrated circuit (IC) package, die) and/or a base (e.g., device package base, package substrate, printed circuit board (PCB), interposer) that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that provides an electrical path for a signal (e.g., data signal, ground signal, power signal). An interconnect may include more than one element/component.

### Exemplary Package Comprising High Aspect Ratio (HAR) Interconnect

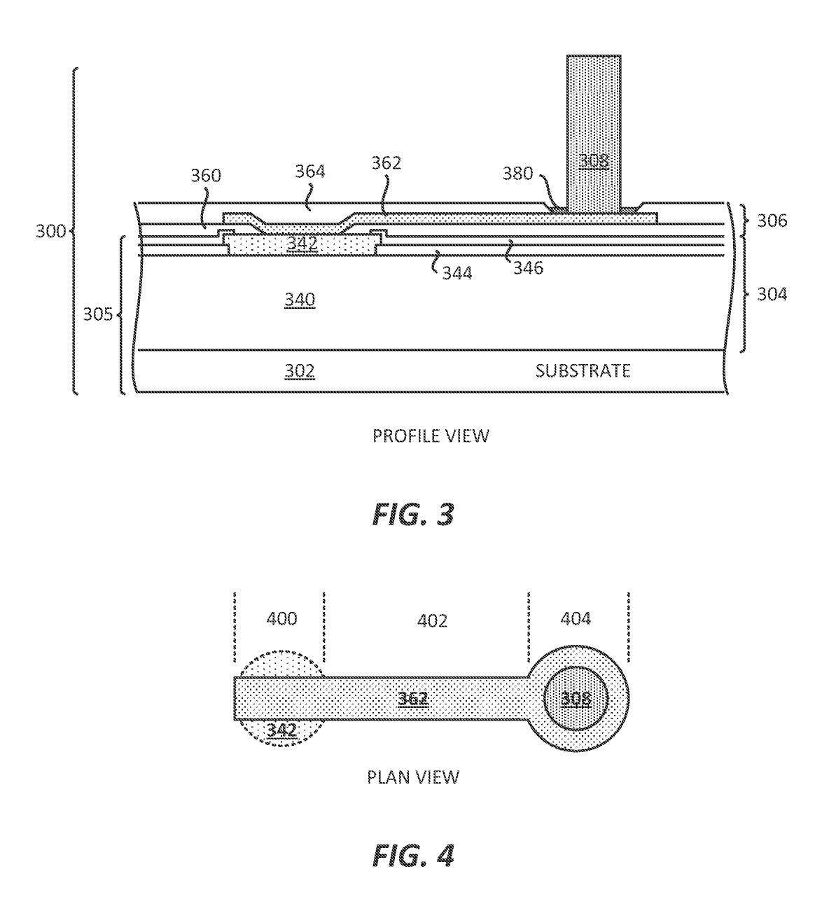

FIG. 3 illustrates a profile view of a package 300 that includes at least one high aspect ratio interconnect. The package 300 may be a wafer level package (WLP). The package 300 includes a substrate 302, an inner portion 304, a redistribution portion 306, and at least one high aspect ratio (HAR) interconnect 308. In some implementations, the substrate 302 and the inner portion 304 may form a die 305 (e.g., bare die) of the package 300.

The substrate 302 may include silicon, glass and/or ceramic. The inner portion 304 is coupled to the substrate 302. The inner portion 304 includes at least one dielectric layer 340 (e.g., lower level dielectric layers), at least one pad 342, a first passivation layer 344 and a second passivation layer 346. The at least one pad 342 and the first passivation layer 344 is on the at least one dielectric layer 340. In some implementations, there is one passivation layer. In some implementations, the first passivation layer 344 and the second passivation layer 346 may be the same passivation layer that is part of one of the at least one dielectric layer 340.

The inner portion 304 may also include several metal layers (e.g., lower level metal layers) that are located in the at least one dielectric layer 340. These metal layers (e.g., M1 metal layer, M2 metal layer, M3 metal layer, M4 metal layer, M5 metal layer, M6 metal layer, M7 metal layer), which are not shown, in the at least one dielectric layer 340 may define interconnects (e.g., traces, vias) in the inner portion 304 of the package 300. In some implementations, the at least one pad 342 may be over a top level metal layer of the inner portion 304 of the package 300. The at least one pad 342 may be coupled (e.g., directly coupled) to a metal layer (e.g., M7 metal layer) of the inner portion 304 of the package 300. The at least one pad 342 may include aluminum. In some implementations, the substrate 302 and/or the inner portion 304 of the package 300 may include several transistors and/or other electronic components. As mentioned above, the substrate 302 and the inner portion 304 may form a die 305 (e.g., bare die) of the package 300.

The redistribution portion 306 is coupled to the die 305. More specifically, the redistribution portion 306 is coupled to the inner portion 304. The redistribution portion 306 includes a first insulation layer 360, a first redistribution metal layer 362, and a second insulation layer 364. In some implementations, the first insulation layer 360 and/or the second insulation layer 364 may include one or more of a polyimide layer (PI), a Polybenzoxazole (PBO) and/or other polymer layers. The first insulation layer 360 is located on the second passivation layer 346.

In some implementations, the redistribution portion 306 allows signals from input/output (I/O) pads of the die 305 to be available (e.g., fan out) in other locations of the package 300. In some implementations, the first redistribution metal layer 362 redistribute signaling from the I/O pads (e.g., pad 342) of the die 305 to other locations in the package 300. The redistribution portion 306 may have different thicknesses. In some implementations, the redistribution portion 306 may have a thickness of about 50 microns (μm) or less.

The redistribution metal layer 362 is coupled (e.g., directly coupled) to the at least one pad 342. A redistribution layer or a redistribution metal layer is a metal layer of a redistribution portion of a package, a wafer level package, an integrated circuit (IC) package and/or a device package. A redistribution layer may include one or more redistribution interconnects, which are formed on the same metal layer of the redistribution portion. A redistribution portion of an integrated circuit (IC) package or device package may include several redistribution layers, each redistribution layer may include one or more redistribution interconnects. Thus, for example, a redistribution portion may include a first redistribution interconnect on a first redistribution metal layer, and a second redistribution interconnect on a second redistribution metal layer that is different than the first redistribution metal layer. The redistribution metal layer 362 is on the first insulation layer 360. The second insulation layer 364 is on the redistribution metal layer 362 and/or the first insulation layer 360.

There is an opening and/or cavity in the second insulation layer 364 such that part of the redistribution metal layer 362 is exposed. The high aspect ratio (HAR) interconnect 308 may be coupled to the redistribution metal layer 362 through the opening in the second insulation layer 364. The high aspect ratio (HAR) interconnect 308 may be coupled to the redistribution metal layer 362 through a solder interconnect 380. The high aspect ratio (HAR) interconnect 308 includes a first surface (e.g., bottom surface), a second surface (e.g., top surface) and a third surface (e.g., side surface). In some implementations, the first surface of the high aspect ratio (HAR) interconnect 308 is coupled to the redistribution metal layer 362. In some implementations, the high aspect ratio (HAR) interconnect 308 and the solder interconnect 380 are part of the package 300. A reflow process may be used to couple (e.g., bond) the high aspect ratio (HAR) interconnect 308 and the solder interconnect 380 to the package 300.

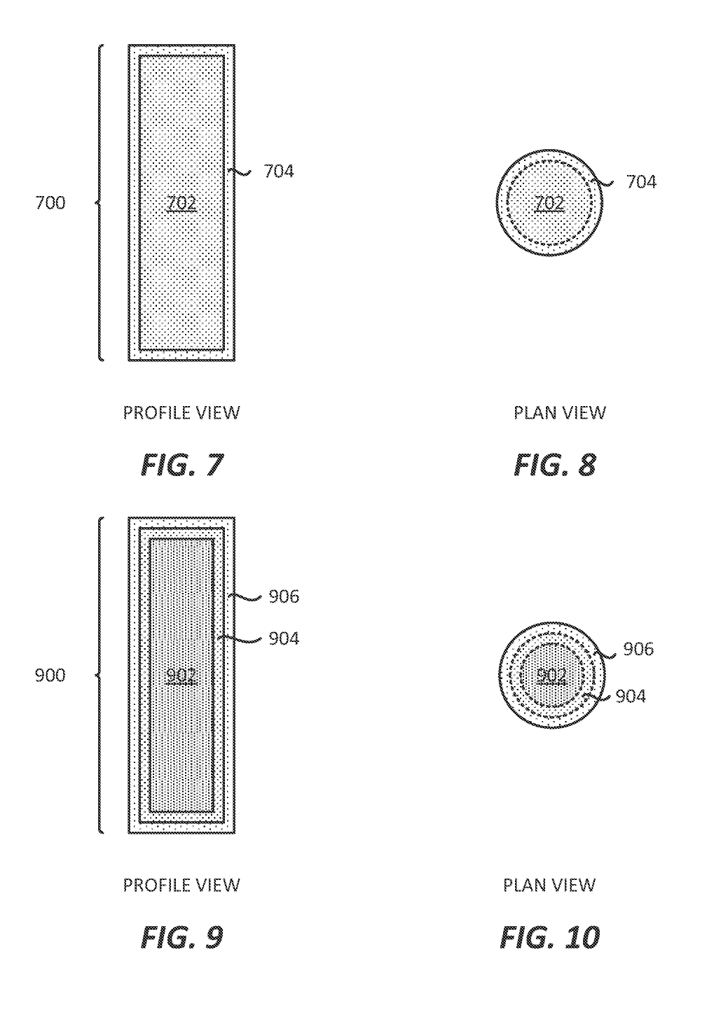

The high aspect ratio (HAR) interconnect 308 may have a width to height aspect ratio of about at least 1:2. In some implementations, the high aspect ratio (HAR) interconnect 308 may have a width to height aspect ratio of about 1:5. The use of several high aspect ratio (HAR) interconnects (e.g., high aspect ratio interconnect 308) allows for high density connections between a package and a package substrate, a printed circuit board (PCB), or any other device, since the pitch between high aspect ratio interconnects may be substantially less than the pitch between solder balls. In some implementations, the pitch between two adjacent high aspect ratio interconnects may be about 300 microns (μm) or less. In some implementations, the pitch between two adjacent high aspect ratio interconnects may be about 100 microns (μm) or greater. In some implementations, the high aspect ratio interconnect 308 may have a width or diameter of about 15 microns (μm) or greater. In some implementations, the high aspect ratio (HAR) interconnect 308 may have a height of about 75 microns (μm) or less. More detailed examples of high aspect ratio (HAR) interconnects are further illustrated and described below in at least FIGS. 7-10.

FIG. 4 illustrates a plan view of a redistribution metal layer of a redistribution portion of a package. As shown in FIG. 4, the redistribution metal layer 362 defines a redistribution interconnect that includes a first redistribution interconnect portion 400, a second redistribution interconnect portion 402, and a third redistribution interconnect portion 404. The first redistribution interconnect portion 400 is coupled to the pad 342. The first redistribution interconnect portion 400 is coupled to the second redistribution interconnect portion 402. The second redistribution interconnect portion 402 may be a redistribution trace. The second redistribution interconnect portion 402 is coupled to the third redistribution interconnect portion 404. The third redistribution interconnect portion 404 may be a redistribution pad. The third redistribution interconnect portion 404 is coupled to the high aspect ratio (HAR) interconnect 308. The high aspect ratio (HAR) interconnect 308 includes a first surface (e.g., bottom surface), a second surface (e.g., top surface) and a third surface (e.g., side surface). In some implementations, the first surface of the high aspect ratio (HAR) interconnect 308 is coupled to the third redistribution interconnect portion 404. FIG. 4 illustrates that the high aspect ratio (HAR) interconnect 308 is positioned over (e.g., on) the redistribution metal layer 362. However, in some implementations, there may be a cavity (not shown) in the redistribution metal layer 362, and the high aspect ratio (HAR) interconnect 308 is coupled to the redistribution metal layer 362 through the cavity such that the redistribution metal layer 362 surrounds (e.g., along a lateral cross sectional plane) the high aspect ratio (HAR) interconnect 308. It is noted that different implementations may use different shapes, designs, and/or sizes for the third redistribution interconnect portion 404. Different implementations may provide at least one high aspect ratio interconnect that is coupled to the package differently.

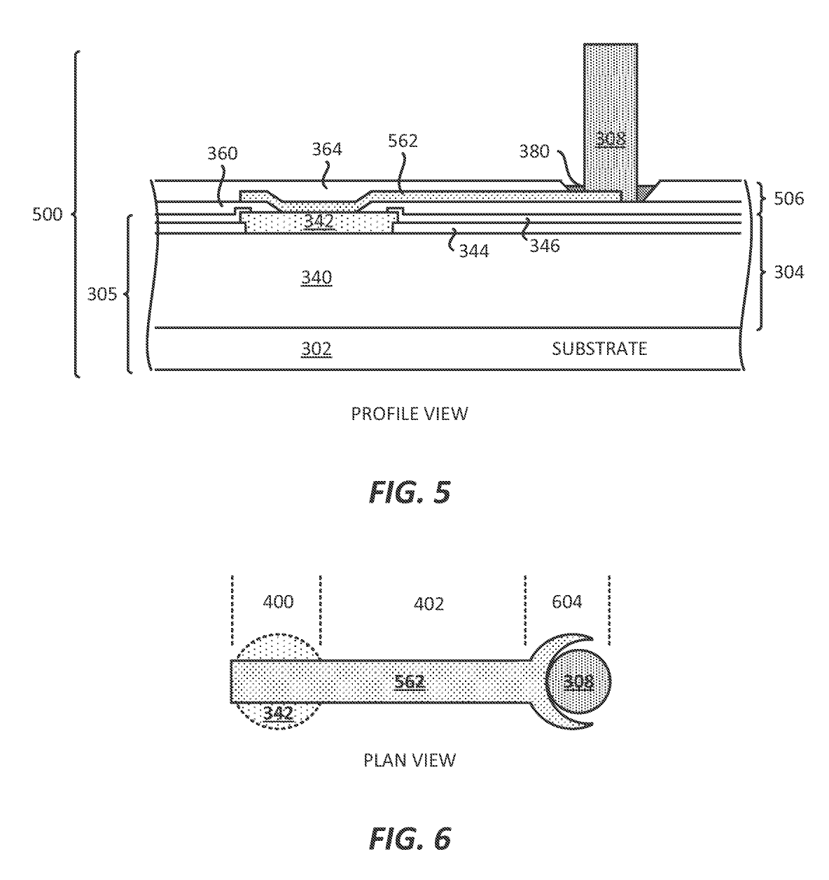

FIG. 5 illustrates a profile view of another package 500 that includes at least one high aspect ratio interconnect. The package 500 may be a wafer level package (WLP). The package 500 includes the substrate 302, the inner portion 304, a redistribution portion 506, and at least one high aspect ratio interconnect 308.

The package 500 is similar to the package 300, as described in FIG. 3, except that a high aspect ratio interconnect is coupled differently to the redistribution portion of the package 500. The substrate 302 and the inner portion 304 of FIG. 5 may be similar to the substrate and inner portion as described in FIG. 3.

The redistribution portion 506 includes the first insulation layer 360, a redistribution metal layer 562, and the second insulation layer 364. The redistribution portion 506 may have different thicknesses. In some implementations, the redistribution portion 506 may have a thickness of about 50 microns (μm) or less.

The high aspect ratio (HAR) interconnect 308 is coupled to the redistribution metal layer 562. The high aspect ratio (HAR) interconnect 308 may be coupled to the redistribution metal layer 562 through the solder interconnect 380. The high aspect ratio (HAR) interconnect 308 includes a first surface (e.g., bottom surface), a second surface (e.g., top surface) and a third surface (e.g., side surface). The first surface of the high aspect ratio (HAR) interconnect 308 is on the first insulation layer 360. In some implementations, the third surface (e.g., side surface) of the high aspect ratio (HAR) interconnect 308 is coupled to the redistribution metal layer 562. In some implementations, the third surface of the high aspect ratio (HAR) interconnect 308 is not in direct contact with the redistribution metal layer 562. Instead, the third surface of the high aspect ratio (HAR) interconnect 308 is coupled to the redistribution metal layer 562 through the solder interconnect 380. In some implementations, the high aspect ratio (HAR) interconnect 308 and the solder interconnect 380 are part of the package 500. A reflow process may be used to couple (e.g., bond) the high aspect ratio (HAR) interconnect 308 and the solder interconnect 380 to the package 500.

FIG. 6 illustrates a plan view of a redistribution metal layer of a redistribution portion of a package. As shown in FIG. 6, the redistribution metal layer 562 defines a redistribution interconnect that includes the first redistribution interconnect portion 400, the second redistribution interconnect portion 402, and a third redistribution interconnect portion 604. The first redistribution interconnect portion 400 is coupled to the pad 342. The first redistribution interconnect portion 400 is coupled to the second redistribution interconnect portion 402. The second redistribution interconnect portion 402 may be a redistribution trace. The second redistribution interconnect portion 402 is coupled to the third redistribution interconnect portion 604. The third redistribution interconnect portion 604 may be a redistribution pad. The third redistribution interconnect portion 604 is coupled to the high aspect ratio (HAR) interconnect 308. The high aspect ratio (HAR) interconnect 308 includes a first surface (e.g., bottom surface), a second surface (e.g., top surface) and a third surface (e.g., side surface). In some implementations, the third surface (e.g., side surface) of the high aspect ratio (HAR) interconnect 308 is coupled to the third redistribution interconnect portion 604. In some implementations, the third surface of the high aspect ratio (HAR) interconnect 308 is not in direct contact with the third redistribution interconnect portion 604. Instead, the third surface (e.g. side surface) of the high aspect ratio (HAR) interconnect 308 is coupled to the third redistribution interconnect portion 604 through the solder interconnect 380. In some implementations, this allows the high aspect ratio (HAR) interconnect 308 to be placed in a smaller footprint area to the capture pad of third redistribution interconnect portion 604, which then allows for finer pitch spacing between high aspect ratio (HAR) interconnects. FIG. 6 illustrates that the redistribution metal layer 562 at least partially surrounds (e.g., along a lateral cross sectional plane) the high aspect ratio (HAR) interconnect 308. In some implementations, the redistribution metal layer 562 surrounds (e.g., completely surrounds along a lateral plane) the high aspect ratio (HAR) interconnect 308. It is noted that different implementations may use different shapes, designs, and/o sizes for the third redistribution interconnect portion 604.

FIGS. 3 and 5 illustrate packages with one high aspect ratio (HAR) interconnect. However, a package (e.g., wafer level package) may include several high aspect ratio (HAR) interconnects (e.g., first high aspect ratio (HAR) interconnect, second high aspect ratio (HAR) interconnect). These high aspect ratio (HAR) interconnects may provide for high density connections to and from a package due to the substantial lower pitch that is possible by using these high aspect ratio (HAR) interconnects.

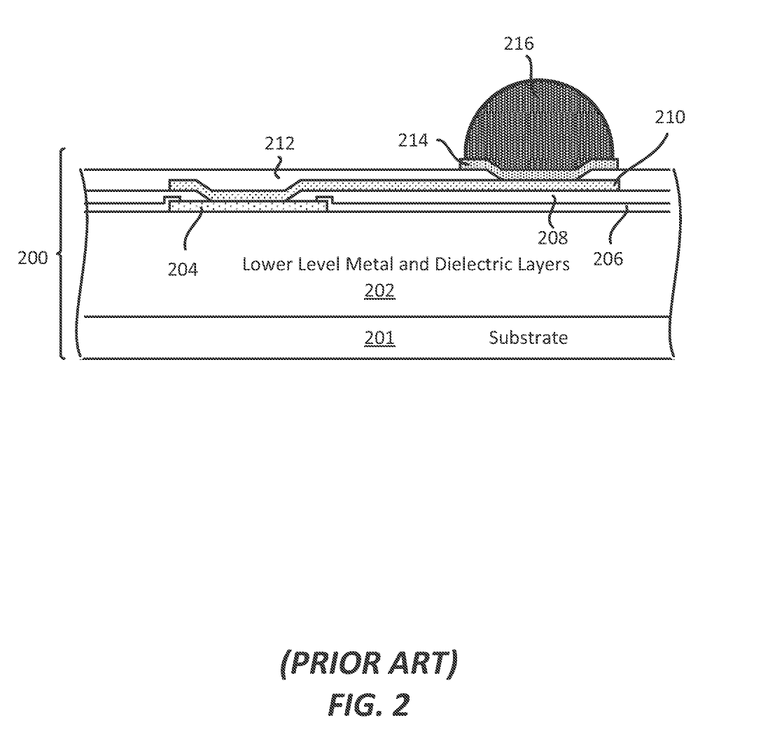

FIGS. 3 and 5 illustrate that the high aspect ratio (HAR) interconnects are coupled to a redistribution metal layer of a package (e.g., wafer level package). However, in some implementations, the package (e.g., wafer level package) may include an under bump metallization (UBM) layer that is coupled to the redistribution metal layer (FIG. 2 illustrates an example of a package with a UBM layer). In such instances, the high aspect ratio (HAR) interconnect may be coupled to the UBM layer.

It is noted that the package 300 and the package 500 may, in some implementations, also include an encapsulation layer (which is not shown in FIGS. 3 and 5). The encapsulation layer, which may be a mold or epoxy fill, may at least partially encapsulate the substrate 302 and the at least one dielectric layer 340. For example, the encapsulation layer may at least partially encapsulate the die 305. In some implementations, the encapsulation layer may be coupled to the redistribution portion 306 or the redistribution portion 506. FIG. 15 below illustrates an example of a package (e.g., wafer level package) that includes an encapsulation layer.

### Exemplary High Aspect Ratio Interconnects

The present disclosure describes high aspect ratio interconnects for providing high density connections between a package and a printed circuit board (PCB) and/or other devices. In FIGS. 3 and 5, the high aspect ratio (HAR) interconnect 308 is comprised of a single electrically conductive material (e.g., copper). However, a high aspect ratio (HAR) interconnect may include different compositions, sizes, shapes, and/or designs. A high aspect ratio (HAR) interconnect may have a width (e.g., diameter) to height ratio of about at least 1:2. In some implementations, a high aspect ratio interconnect may have a width to height ratio of about 1:5.

FIG. 7 illustrates a profile view of a high aspect ratio interconnect 700. In some implementations, the high aspect ratio interconnect 700 may be the high aspect ratio (HAR) interconnect 308 mentioned above, or any other high aspect ratio interconnects described in the present disclosure. The high aspect ratio interconnect 700 may be a composite interconnect comprising several materials. The high aspect ratio interconnect 700 includes a first conductive core 702 (e.g., first electrically conductive core) and a first conductive layer 704 (e.g., first electrically conductive layer). The first conductive layer 704 at least partially encapsulates (e.g., completely encapsulates) the first conductive core 702. As shown in FIG. 7, the first conductive core 702 includes a first surface (e.g., bottom surface), a second surface (e.g., top surface), a third surface (e.g., side surface). The first conductive layer 704 at least partially encapsulates the first surface, the second surface and the third surface of the first conductive core 702.

In some implementations, the width (e.g., diameter) of the high aspect ratio interconnect 700 may be about 50 microns (μm) or less. In some implementations, the height of the high aspect ratio interconnect 700 may be about 500 microns (μm) or less.

Different implementations may use different materials for the high aspect ratio interconnect 700. In some implementations, the first conductive core 702 includes copper and the first conductive layer 704 includes nickel, tin, silver and/or copper. In some implementations, the first conductive layer 704 is a diffusion barrier that prevents a first metal (e.g., copper, first conductive core 702) from migrating into a solder (e.g., solder interconnect).

FIG. 8 illustrates a plan view of the high aspect ratio interconnect 700. As shown in FIG. 8, the first conductive layer 704 at least partially encapsulates the first conductive core 702.

FIG. 9 illustrates a profile view of another high aspect ratio interconnect 900. In some implementations, the high aspect ratio interconnect 900 may be the high aspect ratio interconnect 308 mentioned above, or any other high aspect ratio interconnects described in the present disclosure. The high aspect ratio interconnect 900 may be a composite interconnect comprising several materials. The high aspect ratio interconnect 900 includes a first conductive core 902 (e.g., first electrically conductive core), a first conductive layer 904 (e.g., first electrically conductive layer), and a second conductive layer 906 (e.g., second electrically conductive layer). The first conductive layer 904 at least partially encapsulates (e.g., completely encapsulates) the first conductive core 902. As shown in FIG. 9, the first conductive core 902 includes a first surface (e.g., bottom surface), a second surface (e.g., top surface), a third surface (e.g., side surface). The first conductive layer 904 at least partially encapsulates (e.g., completely encapsulates) the first surface, the second surface and the third surface of the first conductive core 902. The second conductive layer 906 at least partially encapsulates (e.g., completely encapsulates) the first conductive layer 904.

In some implementations, the width (e.g., diameter) of the high aspect ratio interconnect 900 may be about 50 microns (μm) or less. In some implementations, the height of the high aspect ratio interconnect 900 may be about 500 microns (μm) or less.

Different implementations may use different materials for the high aspect ratio interconnect 900. In some implementations, the first conductive core 902 includes copper. In some implementations, the first conductive layer 904 and the second conductive layer 906 includes nickel, tin, silver and/or copper. In some implementations, the first conductive layer 904 and/or the second conductive layer 906 is a diffusion barrier that prevents a first metal (e.g., copper, first conductive core 902) from migrating into a solder (e.g., solder interconnect).

FIG. 10 illustrates a plan view of the high aspect ratio interconnect 900. As shown in FIG. 10, the first conductive layer 904 at least partially encapsulates the first conductive core 902, and the second conductive layer 906 at least partially encapsulates the first conductive layer 904.

In some implementations, a technical advantage of using several conductive layers is that one of the conductive layers may be use a diffusion barrier that prevents one layer from diffusing into another layer. For example, the first conductive layer 904 may be used a barrier layer between the first conductive core 902 and the second conductive layer 906. In some implementations, the first conductive core 902 may be copper and the first conductive layer 904 may be nickel. In some implementations, the second conductive layer 906 may include solder. In such instances, the nickel may act as a diffusion barrier between the copper and the solder, where the diffusion barrier prevents migration of a metal (e.g., copper) into the solder, thus providing for a more robust and better performing interconnect.

### Exemplary Sequence for Coupling a Package Comprising a High Aspect Ratio (HAR) Interconnect to a Printed Circuit Board (PCB)

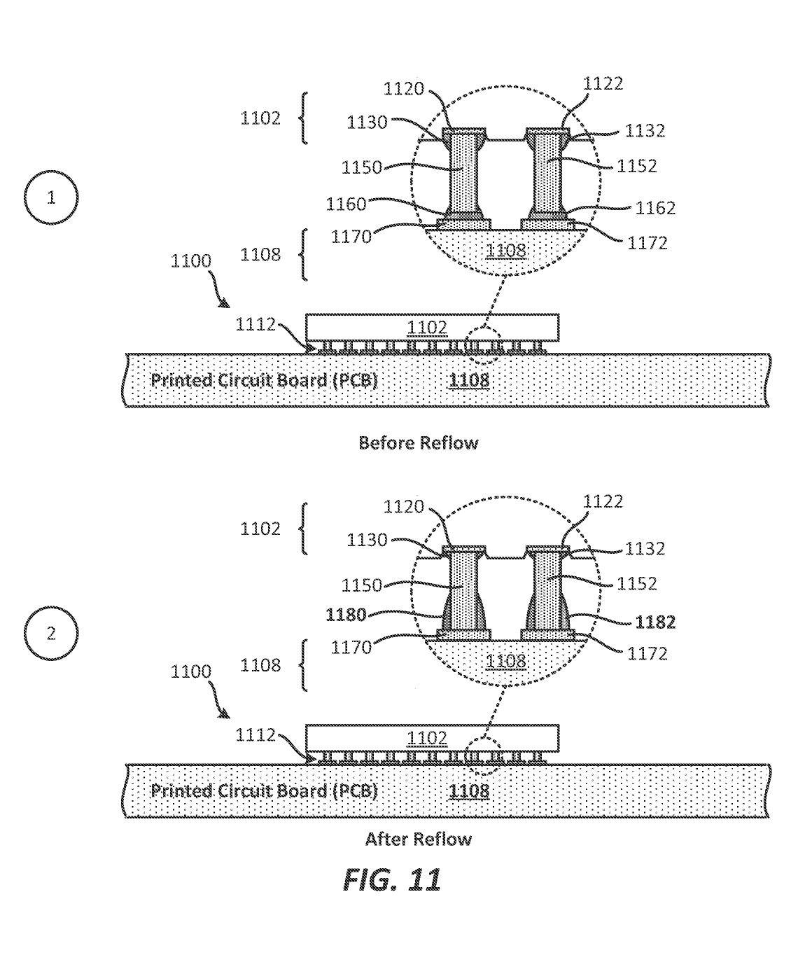

FIG. 11 illustrates an exemplary sequence for coupling a package 1102 (e.g., wafer level package) that includes at least one high aspect ratio interconnect, to a printed circuit board (PCB) 1108. In some implementations, the package 1102 and the printed circuit board (PCB) 1108 of FIG. 11 may be implemented in a device (e.g., integrated device, electronic device).

Stage 1 of FIG. 11 illustrates a state after the package 1102 is mounted on the printed circuit board (PCB) 1108, but before a reflow process is applied to couple (e.g., bond) the package 1102 to the PCB 1108, through several high aspect ratio interconnects 1112. The package 1102 may be a wafer level package (WLP). The package 1102 may be the package 300 or the package 500 as described above in FIGS. 3 and/or 5, or any of the packages described in the present disclosure. At least one of interconnect from the high aspect ratio interconnects 1112 may be any of the high aspect ratio interconnects described in the present disclosure. For example, at least one of the high aspect ratio interconnects 1112 may the high aspect ratio interconnects 308, 700 or 900.

The high aspect ratio interconnects 1112 includes a first interconnect 1150 and a second interconnect 1152. The first interconnect 1150 and/or the second interconnect 1152 may be any of the high aspect ratio interconnects described in the present disclosure.

Stage 1 illustrates that the first interconnect 1150 is coupled to a first redistribution metal layer 1120 of the package 1102. A first solder interconnect 1130 may be used to couple the first interconnect 1150 to the first redistribution metal layer 1120. Prior to stage 1, a reflow process may have been previously used to couple (e.g. bond) the first interconnect 1150 to the first redistribution metal layer 1120 through the first solder interconnect 1130. The first interconnect 1150 is also coupled to a first pad 1170 of the PCB 1108, through a second solder interconnect 1160. At stage 1, a reflow process has not yet been applied to couple (e.g., bond) the first interconnect 1150 to the PCB 1108 through the second solder interconnect 1160.

Stage 1 further illustrates that the second interconnect 1152 is coupled to a second redistribution metal layer 1122 of the package 1102. A third solder interconnect 1132 may be used to couple the second interconnect 1152 to the second redistribution metal layer 1122. Prior to stage 1, a reflow process may have been previously used to couple the second interconnect 1152 to the second redistribution metal layer 1122 through the third solder interconnect 1132. The second interconnect 1152 is also coupled to a second pad 1172 of the PCB 1108, through a fourth solder interconnect 1162. At stage 1, a reflow process has not yet been applied to couple (e.g., bond) the second interconnect 1152 to the PCB 1108 through the fourth solder interconnect 1162.

Stage 2 illustrates a state after a reflow process has been applied to couple (e.g., bond) the package 1102 to the PCB 1108, through the several high aspect ratio interconnects 1112. As shown at stage 2, a first solder interconnect 1180 couples the first interconnect 1150 to the first pad 1170, and a second solder interconnect 1182 couples the second interconnect 1152 to the second pad 1172.

The first solder interconnect 1180 is a combination of some solder from the first solder interconnect 1130 and the second solder interconnect 1160. Similarly, the second solder interconnect 1182 is a combination of some solder from the third solder interconnect 1132 and the fourth solder interconnect 1162.

As shown at stage 2, there is less solder from the first solder interconnect 1130 that couples the first interconnect 1150 to the first redistribution metal layer 1120. Some of the solder from the first solder interconnect 1130 has flowed towards the first pad 1170 during the reflow process to combine with the second solder interconnect 1160 to form the first solder interconnect 1180. Similarly, there is less solder from the third solder interconnect 1132 that couples the second interconnect 1152 to the second redistribution metal layer 1122. Some of the solder from the third solder interconnect 1132 has flowed towards the second pad 1172 during the reflow process to combine with the fourth solder interconnect 1162 to form the second solder interconnect 1182.

As further shown at stage 2, the first solder interconnect 1180 wets part of the side wall of the first interconnect 1150. In some implementations, the first solder interconnect 1180 may wet the side wall of the first interconnect 1150 such that the first solder interconnect 1180 has a height of about at least 25 percent of the height of the first interconnect 1150.

Similarly, as shown at stage 2, the second solder interconnect 1182 wets part of the side wall of the second interconnect 1152. In some implementations, the second solder interconnect 1182 may wet the side wall of the second interconnect 1152 such that the second solder interconnect 1182 has a height of about at least 25 percent of the height of the second interconnect 1152.

In some implementations, at least a substantial part (e.g., more than 50 percent, completely) of the outer wall of the first interconnect 1150 is covered by the first solder interconnect 1130 and/or the first solder interconnect 1180, after the reflow process. Similarly, in some implementations, at least a substantial part of the outer wall of the second interconnect 1152 is covered by the third solder interconnect 1132 and/or the second solder interconnect 1182 after the reflow process. In some implementations, after the reflow process, there may be solder between the first interconnect 1150 and the first pad 1170. Similarly, in some implementations, after the reflow process, there may be solder between the second interconnect 1152 and the second pad 1172.

In some implementations, having solder on the outer wall and/or side wall of the interconnect (e.g., first interconnect 1150) provides for better electrical signal performance between the package 1102 and the PCB 1108. In some implementations, the first interconnect 1150 and/or the second interconnect 1152 may include a diffusion barrier layer (e.g., nickel) to prevent copper from diffusing into the solder, which provides for more robust and better performing interconnects.

In some implementations, the pitch between two adjacent high aspect ratio interconnects may be about 300 microns (μm) or less. In some implementations, the pitch between two adjacent high aspect ratio interconnects may be about 100 microns (μm) or greater.

Exemplary Sequence for Fabricating a Package that Includes High Aspect Ratio Interconnects

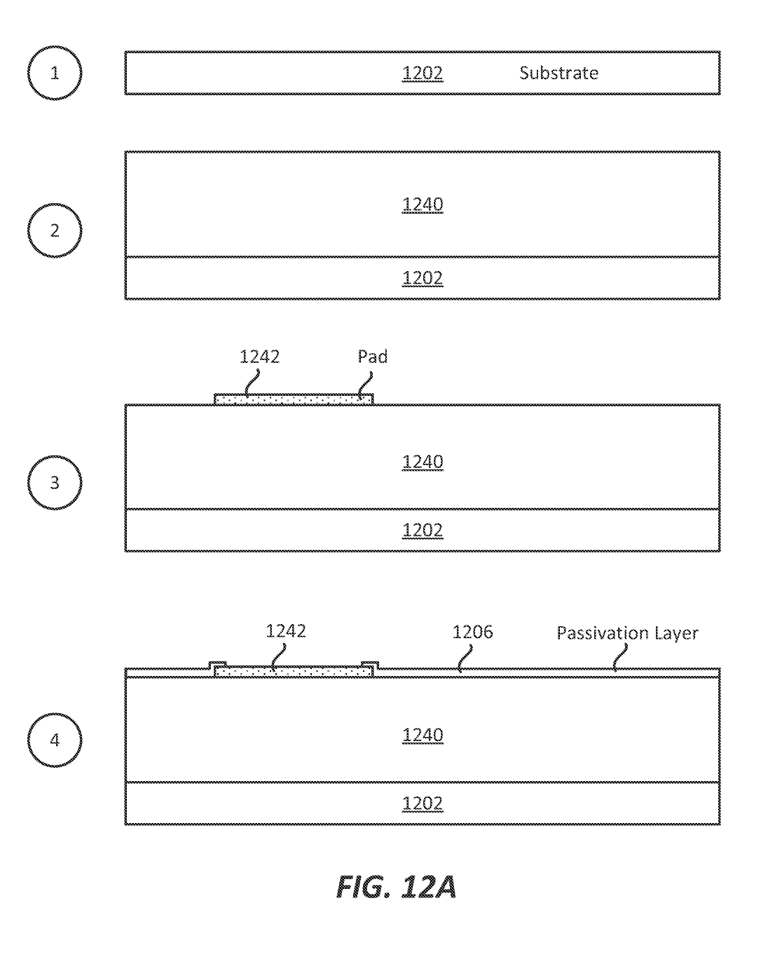

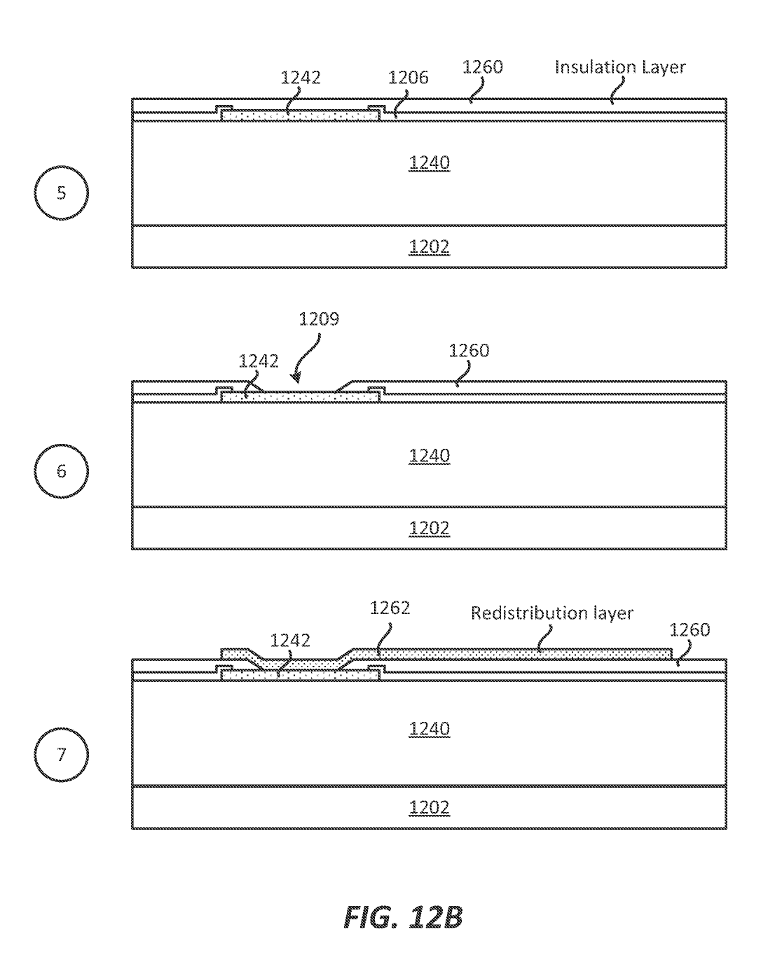

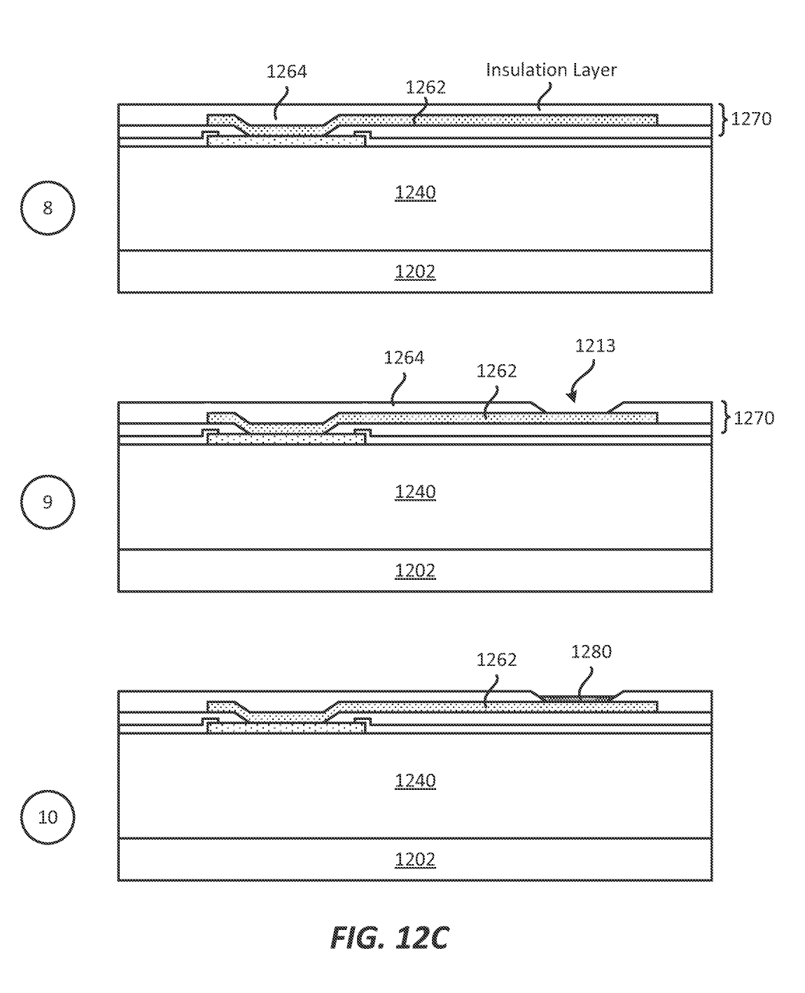

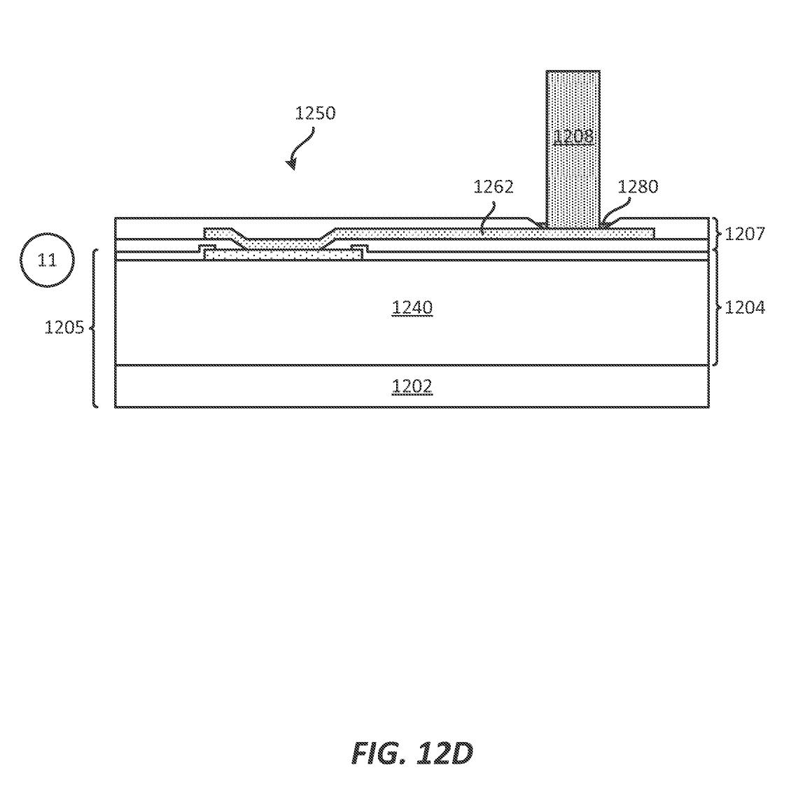

In some implementations, fabricating a package that includes at least one high aspect ratio interconnect includes several processes. FIG. 12 (which includes FIGS. 12A-12D) illustrates an exemplary sequence for providing or fabricating a package (e.g., wafer level package) that includes at least one high aspect ratio interconnect. In some implementations, the sequence of FIGS. 12A-12D may be used to provide or fabricate the packages of FIGS. 3, 5 and/or other packages described in the present disclosure.

It should be noted that the sequence of FIGS. 12A-12D may combine one or more stages in order to simplify and/or clarify the sequence for providing or fabricating a package that includes at least one high aspect ratio interconnect. In some implementations, the order of the processes may be changed or modified.

Stage 1 of FIG. 12A illustrates a state after a substrate (e.g., substrate 1202) is provided. Different implementations may use different materials for the substrate (e.g., silicon substrate, glass substrate, ceramic substrate). The substrate may be a wafer.

Stage 2 illustrates a state after at least one lower level dielectric layer 1240 is provided (e.g., formed) on the substrate. The at least one lower dielectric layer 1240 may include several lower level metal layers (e.g., M1 metal layer, M2 metal layer, M3 metal layer, M4 metal layer, M5 metal layer, M6 metal layer, M7 metal layer). For purpose of clarity, these lower level metal layers are not shown. The lower level metal layers may define at least one lower level interconnect (e.g., die interconnects). These lower level interconnects may include traces, vias and/or pads. The lower level metal layers and the at least one lower level dielectric layer may be part of an inner portion of a die, as mentioned in FIG. 3. Different processes may be use to form the lower level metals layers.

Stage 3 illustrates a state after at least one pad (e.g., pad 1242) is provided (e.g., formed) over the at least one lower level dielectric layer 1240. In some implementations, the pad 1242 is coupled to one of the lower level metal layers (not shown). In some implementations, the pad 1242 is a top metal layer. In some implementations, the pad 1242 is an aluminum pad. However, different implementations may use different materials for the pad 1242. Different implementations may use different processes for forming the pad 1242 over the at least one lower level dielectric layer 1240. For example, in some implementations, lithography, etching and/or plating processes may be use to provide the pad 1242 over the at least one lower level dielectric layer 1240.

Stage 4 illustrates a state after a passivation layer (e.g., passivation layer 1206) is formed on the at least one lower level dielectric layer 1240. Different implementations may use different materials for the passivation layer. As shown in stage 4, the passivation layer 1206 is provided on the at least one lower level dielectric layer 1240 such that at least a portion of the pad 1242 is exposed. In some implementations, more than one passivation layer may be formed, as mentioned in FIGS. 3 and 5. In some implementations, stage 4 illustrates a state after a die (e.g., bare die) is provided or fabricated.

Stage 5 of FIG. 12B, illustrates a state after a first insulation layer (e.g., first insulation layer 1260) is provided on the passivation layer 1206 and the pad 1242. Different implementations may use different materials for the first insulation layer 1260. For example, the first insulation layer 1260 may be a polyimide layer (PI), a Polybenzoxazole (PBO) and/or other polymer layer.

Stage 6 illustrates a state after a cavity (e.g., cavity 1209) is provided, created, and/or formed in the first insulation layer 1260. As further shown in stage 6, the cavity 1209 is formed over the pad 1242. Different implementations may form the cavity 1209 differently. For example, the cavity 1209 may be formed by etching the first insulation layer 1260.

Stage 7 illustrates a state after a first redistribution metal layer (e.g., first redistribution metal layer 1262) is formed. Specifically, the first redistribution metal layer 1262 is formed over the pad 1242 and the first insulation layer 1260. As shown in stage 7, the first redistribution metal layer 1262 is coupled to the pad 1242. In some implementations, the first redistribution metal layer 1262 is a copper layer. One or more plating processes may be used to form the first redistribution metal layer 1262.

Stage 8 of FIG. 12C, illustrates a state after a second insulation layer (e.g., second insulation layer 1264) is provided (e.g., formed) on the first insulation layer 1260 and the first redistribution metal layer 1262. Different implementations may use different materials for the second insulation layer 1264. For example, the second insulation layer 1264 may be a polyimide layer (PI), a Polybenzoxazole (PBO) and/or other polymer layer. The first insulation layer 1260, the first redistribution metal layer 1262, and the second insulation layer 1264 may be part of a redistribution portion 1270 of a package.

Stage 9 illustrates a state after a cavity (e.g., cavity 1213) is provided, created, and/or formed in the second insulation layer 1264. Different implementations may form the cavity 1213 differently. For example, the cavity 1213 may be formed by etching the second insulation layer 1264.

Stage 10 illustrates a state after a solder interconnect (e.g., solder interconnect 1280) is formed in the cavity 1213. The solder interconnect 1280 may be formed in the cavity 1213 and on an exposed portion of the first redistribution metal layer 1262. A screen printing process may be used to form the solder interconnect 1280 in the cavity 1213 over the first redistribution metal layer 1262. However different implementations may provide the solder interconnect differently.

Stage 11 of FIG. 12D, illustrates a state after at least one high aspect ratio (HAR) interconnect (e.g., interconnect 1208) is coupled to the first redistribution metal layer 1262. A reflow process may be used to couple the interconnect 1208 to the package through the solder interconnect 1280. The interconnect 1208 may be a pre-formed or pre-fabricated interconnect that includes a high aspect ratio of about at least 1:2. The aspect ratio of the interconnect may be defined as a width (e.g., diameter) to height ratio. Examples of interconnects that may be used in stage 11 are illustrated and described in at least FIGS. 7 and 9, such as high aspect ratio interconnects 700 and 900. As shown in stage 11, the solder interconnect 1280 helps provide coupling between the interconnect 1208 and the first redistribution metal layer 1262. In some implementations, stage 11 illustrates a package 1250 (e.g., wafer level package) that includes a substrate 1202, an inner portion 1204, a redistribution portion 1207, and at least one high aspect ratio interconnect 1208. The substrate 1202 and the inner portion 1204 may form a die 1205 (e.g., bare die) of the package 1250. In some implementations, several high aspect ratio (HAR) interconnects are coupled to the package 1250 (e.g., wafer level package).

It is also noted that several packages, with each package comprising several high aspect ratio (HAR) interconnects may be fabricated (e.g., concurrently fabricated) on a wafer. The wafer is then singulated into individual packages with high aspect ratio (HAR) interconnects. These singulated packages may then be coupled to a printed circuit board (PCB).

Exemplary Flow Diagram of a Method for Fabricating a Package that Includes High Aspect Ratio Interconnects

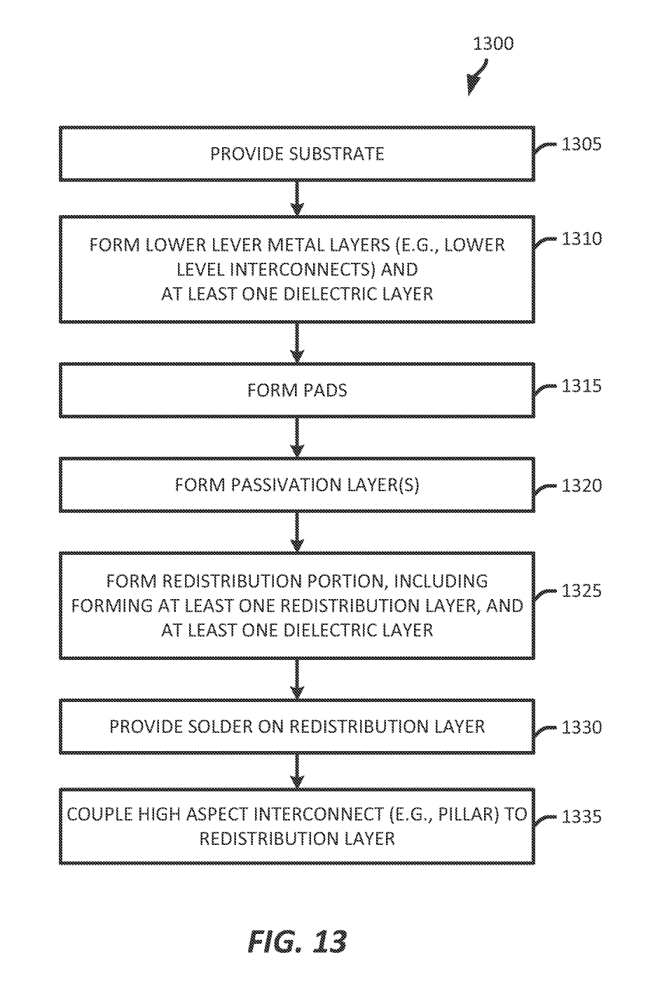

In some implementations, providing a package that includes at least one high aspect ratio interconnect includes several processes. FIG. 13 illustrates an exemplary flow diagram of a method 1300 for providing or fabricating a package (e.g., wafer level package) that includes at least one high aspect ratio interconnect. In some implementations, the method 1300 of FIG. 13 may be used to provide or fabricate the packages of FIGS. 3, 5 and/or other packages described in the present disclosure.

It should be noted that the sequence of FIG. 13 may combine one or more processes in order to simplify and/or clarify the method for providing or fabricating a package that includes at least one high aspect ratio interconnect. In some implementations, the order of the processes may be changed or modified.

The method provides (at 1305) a substrate. Different implementations may use different materials for the substrate (e.g., silicon substrate, glass substrate, ceramic substrate). The substrate may be the substrate 302 or the substrate 1202. The substrate may be a wafer.

The method forms (at 1310) several lower level metal layers and at least one lower level dielectric layer on the substrate. Different implementations may form different number of lower level metal layers and lower level dielectric layers (e.g., M1 metal layer, M2 metal layer, M3 metal layer, M4 metal layer, M5 metal layer, M6 metal layer, M7 metal layer). The at least one dielectric layer may be the at least one dielectric layer 340 or the at least one lower level dielectric layer 1240. The lower level metal layers may define at least one lower level interconnect (e.g., die interconnects). These lower level interconnects may include traces, vias and/or pads. The lower level metal layers and the at least one lower level dielectric layer may be part of an inner portion of a die, as mentioned in FIG. 3. Different processes may be use to form the lower level metals layers.

The method forms (at 1315) at least one pad on the lower level metal layers and the at least one dielectric layer. In some implementations, the pad is formed such that the pad is coupled to one of the lower level metal layers. In some implementations, the pad is a top metal layer. In some implementations, the pad is an aluminum pad. However, different implementations may use different materials for the pad. Different implementations may use different processes for forming the pad. The pad may be the pad 342 or the pad 1242.

The method forms (at 1320) at least one passivation layer on the lower level metal layer and the at least one dielectric layer. Different implementations may use different materials for the passivation layer. The passivation layer may be the first passivation layer 344, the second passivation layer 346 or the passivation layer 1206. In some implementations, forming the lower level metal layers, at least one dielectric layer, at least one pad, and/or at least passivation layer forms defines an inner portion (e.g., inner portion 304) for a die. In some implementations, providing the substrate, forming the metal layers and dielectric layers, forming the pads, and forming the passivation layer provides and forms a die (e.g., bare die).

The method forms (at 1325) a redistribution portion for a package. In some implementations, forming (at 1325) the redistribution portion includes forming at least one insulation layer and at least one redistribution metal layer. Stages 5-9 of FIGS. 12B-12C illustrates an example of forming a redistribution portion, including forming at least one insulation layer and at least one redistribution metal layer. The redistribution portion may be the redistribution portion 306, the redistribution portion 506 or the redistribution portion 1270.

The method provides (at 1330) a solder interconnect on a redistribution metal layer of the redistribution portion. In some implementations, the solder interconnect may be formed in a cavity of an insulation layer and on an exposed portion of a redistribution metal layer. A screen printing process may be used to form the solder interconnect on the redistribution metal layer. Different implementations may form the solder interconnect differently. The solder interconnect may be the solder interconnect 380 or the solder interconnect 1280.

The method couples (at 1335) at least one high aspect ratio interconnect to a redistribution metal layer. The high aspect ratio interconnect may be a pre-formed or pre-fabricated interconnect that has a high aspect ratio of about at least 1:2. The aspect ratio of the interconnect may be defined as a width (e.g., diameter) to height ratio. Examples of interconnects that may be used are illustrated and described in at least FIGS. 7 and 9, such as high aspect ratio interconnects 700 and 900.

It is also noted that the sequence of FIG. 12 may be used to fabricate (e.g., concurrently fabricate) several dies and packages on a wafer, with each package comprising several high aspect ratio (HAR) interconnects. The wafer is then singulated (e.g., cut) into individual packages with high aspect ratio (HAR) interconnects. These singulated packages may then be coupled to a printed circuit board (PCB).

### Exemplary Packages Comprising High Aspect Ratio (HAR) Interconnects

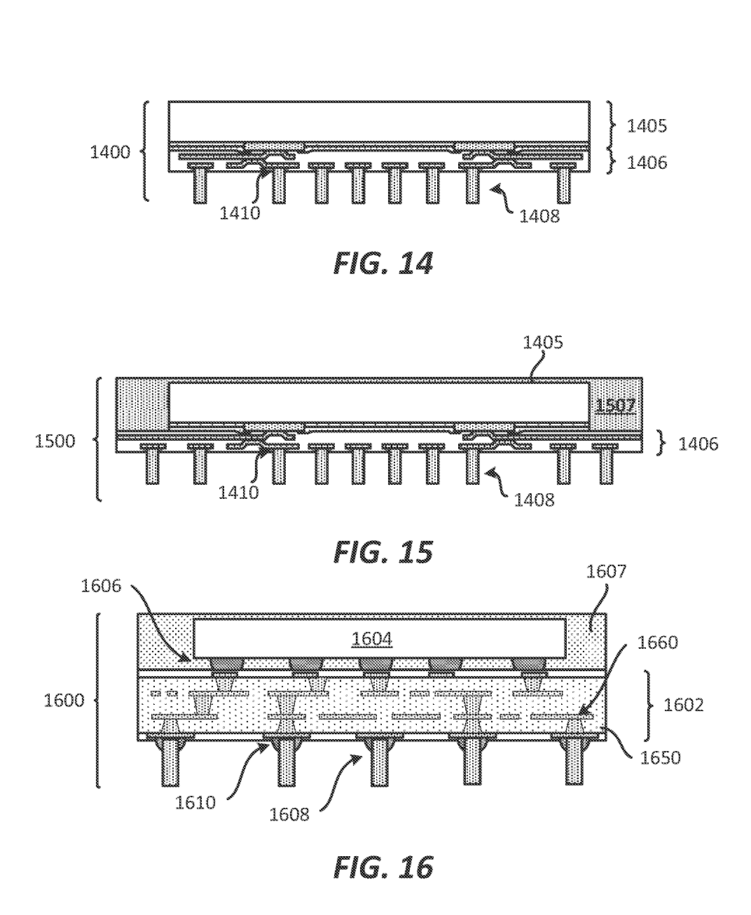

FIG. 14 illustrates a high level profile view of a package 1400 that includes a plurality of high aspect ratio interconnects. The package 1400 may be a wafer level package (WLP).

The package 1400 (e.g., device package) includes a die 1405 (e.g., bare die), a redistribution portion 1406, and a plurality of high aspect ratio (HAR) interconnects 1408. The die 1405 may include the substrate 302 and the inner portion 304, as described in FIGS. 3 and 5. The die 1405 may be similar to the die 305.

The redistribution portion 1406 is coupled to the die 1405. The redistribution portion 1406 may be similar to the redistribution portion 306 or the redistribution portion 506, as described in FIGS. 3 and 5. The plurality of high aspect ratio (HAR) interconnects 1408 is coupled to the redistribution portion 1406 through a plurality of solder interconnects 1410. The plurality of high aspect ratio (HAR) interconnects 1408 may be similar to any of the high aspect ratio (HAR) interconnects described in the present disclosure, such as for example, the high aspect ratio (HAR) interconnect 308, the high aspect ratio (HAR) interconnect 700 and the high aspect ratio (HAR) interconnect 900.

FIG. 15 illustrates a high level profile view of a package 1500 that includes a plurality of high aspect ratio interconnects. The package 1500 may be a wafer level package (WLP). The package 1500 is similar to the package 1400 of FIG. 14, except that the package 1500 includes an encapsulation layer 1507. The encapsulation layer 1507 may at least partially encapsulate the die 1405. The encapsulation layer 1507 is at least partially coupled to the redistribution portion 1406.

FIG. 16 illustrates a high level profile view of a package 1600 that includes a plurality of high aspect ratio interconnects. The package 1600 may be a chip scale package (CSP). The package 1600 includes a package substrate 1602, a die 1604 (e.g., bare die), a plurality of solder balls 1606, an encapsulation layer 1607, a plurality of high aspect ratio interconnects 1608 and a plurality of solder interconnects 1610.

The die 1604 may be a bare die. The die 1604 is coupled to the package substrate 1602 through the plurality of solder balls 1606. The encapsulation layer 1607 at least partially encapsulates the die 1604. The plurality of high aspect ratio interconnects 1608 is coupled to the package substrate 1602 through a plurality of solder interconnects 1610. In some implementations, the plurality of high aspect ratio interconnects 1608 is coupled to the package substrate 1602 through a plurality of solder interconnects 1610, in a manner that is similar to how the high aspect ratio interconnect 308 is coupled to a redistribution portion (e.g., redistribution portion 306, redistribution portion 506). The package substrate 1602 includes at least one dielectric layer 1650 and a plurality of interconnects 1660. In some implementations, the package substrate 1602 has a thickness of about 150 microns (μm).

The present disclosure describes various die and bare dies. It is noted that different implementations may use different variations and designs of a die or bare die.

Exemplary Sequence for Fabricating a Package that Includes a Die and a High Aspect Ratio Interconnect

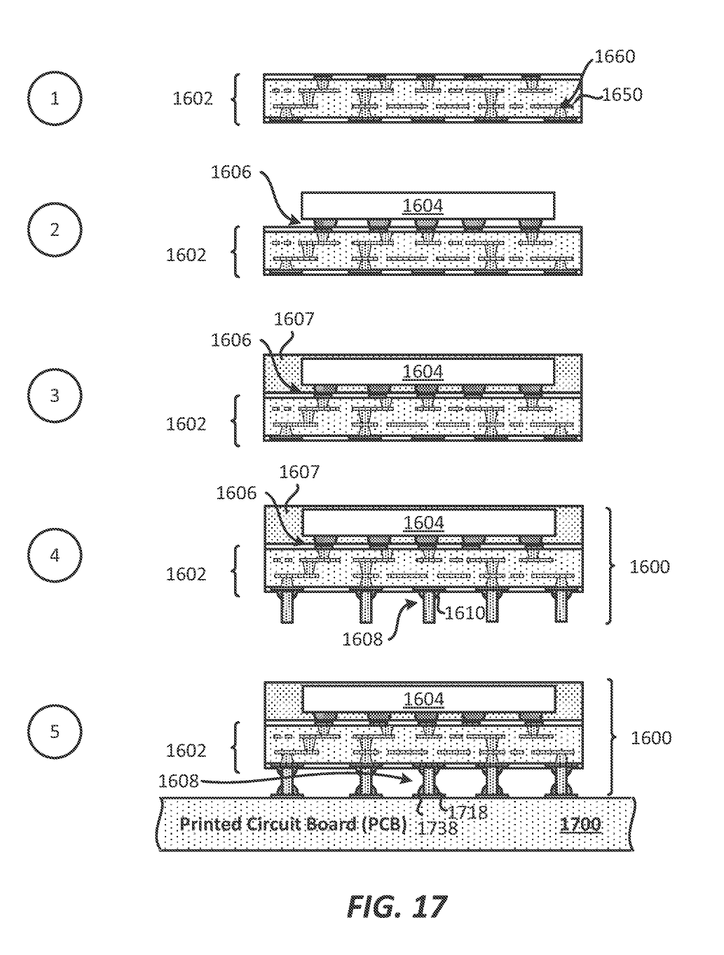

In some implementations, providing a package that includes a die and at least one high aspect ratio interconnect includes several processes. FIG. 17 illustrates an exemplary sequence for providing or fabricating a package that includes a die, a package substrate, and at least one high aspect ratio interconnect. In some implementations, the sequence of FIG. 17 may be used to provide or fabricate the package of FIG. 16 and/or other packages described in the present disclosure.

It should be noted that the sequence of FIG. 17 may combine one or more stages in order to simplify and/or clarify the sequence for providing or fabricating a package that includes at least one high aspect ratio interconnect. In some implementations, the order of the processes may be changed or modified.

Stage 1 of FIG. 17, illustrates a state after a package substrate 1602 is provided. The package substrate 1602 includes at least one dielectric layer 1650 and several interconnects 1660 (e.g., traces, vias, pads).

Stage 2 illustrates a state after a die 1604 is coupled to the package substrate 1602 through a plurality of solder balls 1606. The die 1604 is coupled to the package substrate 1602 on a first side (e.g., the die side) of the package substrate 1602. In some implementations, the die 1604 may be coupled to the package substrate 1602 differently. The die 1604 may be a bare die.

Stage 3 illustrates a state after an encapsulation layer 1607 is formed over the die 1604 and the package substrate 1602. The encapsulation layer 1607 may at least partially encapsulate the die 1604. The encapsulation layer 1607 may comprise a mold and/or an epoxy fill.

Stage 4 illustrates a state after several high aspect ratio interconnects 1608 are coupled to the package substrate 1602. The high aspect ratio interconnects 1608 may be any of the high aspect ratio interconnects described in the present disclosure. In some implementations, a reflow process is performed so that a solder interconnect 1610 wets the high aspect ratio interconnects 1608 and the interconnects (e.g., pads) of the package substrate 1602. The solder interconnect 1610 may be formed on the interconnects (e.g., pads) of the package substrate 1602 before the high aspect ratio interconnects 1608 is coupled to the package substrate 1602. The high aspect ratio interconnects 1608 is coupled to the package substrate 1602 on a second side (e.g., the printed circuit board (PCB) side) of the package substrate 1602. The second side of the package substrate 1602 may be opposite to the first side of the package substrate. Stage 4 illustrates a package 1600 (e.g., chip scale package) that includes the package substrate 1602, the die 1604, the plurality of solder balls 1606, the encapsulation layer 1607, the high aspect ratio interconnects 1608, and the solder interconnect 1610. In some implementations, the package 1600 is a chip scale package (CSP).

Stage 5 illustrates a state after the package 1600 is coupled to a printed circuit board (PCB) 1700 through the several high aspect ratio interconnects 1608. In particular, the package substrate 1602 of the package 1600 is coupled to the printed circuit board (PCB) 1700 through the several high aspect ratio interconnects 1608. The high aspect ratio interconnects 1608 is coupled to the package 1600 through the solder interconnect 1610. For example, the high aspect ratio interconnects 1608 may be coupled to pads of the package substrate 1602 through the solder interconnect 1610. The high aspect ratio interconnect 1608 is coupled to the interconnects 1738 (e.g., pads) of the printed circuit board (PCB) 1700 and the solder interconnect 1718. An example of how solder may wet to the high aspect ratio interconnects 1608 and pads is described in FIG. 11. The high aspect ratio interconnects 1608 are configured to provide high density connections between the package 1600 and the printed circuit board (PCB) 1700. In some implementations, the pitch between two adjacent high aspect ratio interconnects may be about 300 microns (μm) or less. In some implementations, the pitch between two adjacent high aspect ratio interconnects may be about 100 microns (μm) or greater. In some implementations, the high aspect ratio interconnect 1608 may have a width or diameter of about 15 microns (μm) or greater. In some implementations, the high aspect ratio (HAR) interconnect 1608 may have a height of about 75 microns (μm) or less.

### Exemplary Electronic Devices

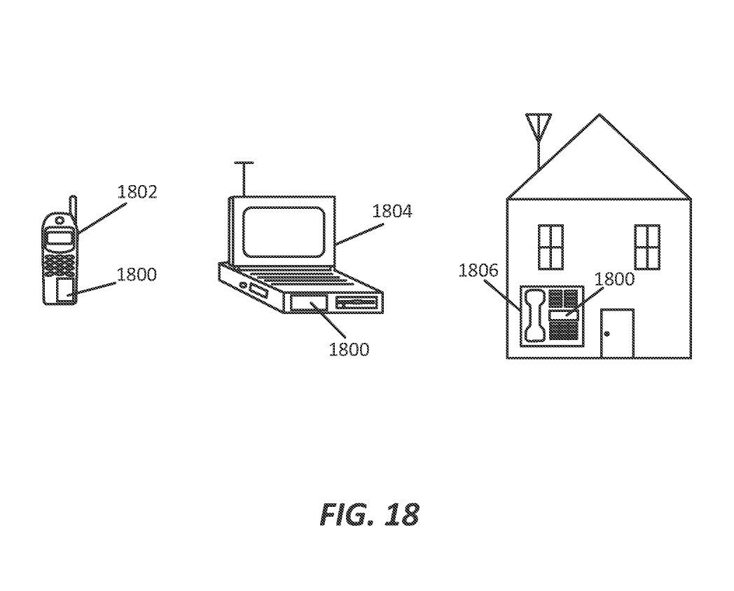

FIG. 18 illustrates various electronic devices that may be integrated with any of the aforementioned integrated device, semiconductor device, integrated circuit (IC) package, die, interposer, package, wafer level package, or package-on-package (PoP). For example, a mobile phone device 1802, a laptop computer device 1804, and a fixed location terminal device 1806 may include an integrated device 1800 as described herein. The integrated device 1800 may be, for example, any of the integrated circuits, dies, integrated devices, integrated device packages, integrated circuit devices, package-on-package devices described herein. The devices 1802, 1804, 1806 illustrated in FIG. 18 are merely exemplary. Other electronic devices may also feature the integrated device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

One or more of the components, features, and/or functions illustrated in FIGS. 3, 4, 5, 6, 7, 8, 9, 10, 11, 12A-12C, 13, 14, 15, 16, 17 and/or 18 may be rearranged and/or combined into a single component, feature or function or embodied in several components, or functions. Additional elements, components, and/or functions may also be added without departing from the disclosure. It should also be noted that FIGS. 3, 4, 5, 6, 7, 8, 9, 10, 11, 12A-12C, 13, 14, 15, 16, 17 and/or 18 and its corresponding description in the present disclosure is not limited to dies and/or ICs. In some implementations, FIGS. 3, 4, 5, 6, 7, 8, 9, 10, 11, 12A-12C, 13, 14, 15, 16, 17 and/or 18 and its corresponding description may be used to manufacture, create, provide, and/or produce integrated devices. In some implementations, a device may include a die, a die package, an integrated circuit (IC), an integrated circuit (IC) package, a device package, a wafer, a semiconductor device, a package on package structure, a wafer level package, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other.

Also, it is noted that the various disclosures may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a die;
a redistribution portion coupled to the die;
a first high aspect ratio (HAR) interconnect coupled to the redistribution portion of the package, wherein the first high aspect ratio (HAR) interconnect comprises a width to height ratio of about at least 1:2; and
a first solder interconnect coupled to the first high aspect ratio (HAR) interconnect and the redistribution portion.

2. The package of claim 1, wherein the first high aspect ratio (HAR) interconnect is a composite interconnect comprising:
a first conductive core; and
a first conductive layer that at least partially encapsulates the first conductive core.

3. The package of claim 2, wherein the first conductive layer is a diffusion barrier.

4. The package of claim 2, wherein the composite interconnect further comprises a second conductive layer that at least partially encapsulates the first conductive layer.

5. The package of claim 2, wherein the first conductive core comprises a first surface, a second surface and a third surface, wherein the first conductive layer at least partially encapsulates the first surface, the second surface and the third surface of the first conductive core.

6. The package of claim 1, wherein the redistribution portion comprises:
an insulation layer; and
a redistribution metal layer that surrounds the first high aspect ratio (HAR) interconnect, along a lateral cross sectional plane of the first high aspect ratio (HAR) interconnect, wherein the first high aspect ratio (HAR) interconnect physically touches the redistribution metal layer.

7. The package of claim 1, wherein the redistribution portion comprises:
an insulation layer, and
a redistribution metal layer that at least partially surrounds the first high aspect ratio (HAR) interconnect, wherein the first high aspect ratio (HAR) interconnect physically touches the insulation layer.

8. The package of claim 1, further comprising a second high aspect ratio (HAR) interconnect, wherein a pitch between the first high aspect ratio (HAR) interconnect and the second high aspect ratio (HAR) interconnect is about 300 microns (μm) or less.

9. The package of claim 1, wherein the package is a wafer level package (WLP).

10. The package of claim 1, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in a automotive vehicle, and further including the device.

11. A device comprising:
a printed circuit board (PCB);
a package coupled to the printed circuit board (PCB), the package comprising:
a die;
a redistribution portion coupled to the die;
a first high aspect ratio (HAR) interconnect coupled to the redistribution portion of the package and the printed circuit board (PCB), wherein the first high aspect ratio (HAR) interconnect comprises a width to height ratio of about at least 1:2; and
a first solder interconnect coupled to the first high aspect ratio (HAR) interconnect and the redistribution portion; and
a second solder interconnect coupled to the first high aspect ratio (HAR) interconnect and the printed circuit board (PCB).

12. The device of claim 11, wherein the second solder interconnect wets about at least 25 percent of the height of the first high aspect ratio (HAR) interconnect.

13. The device of claim 11, wherein the first high aspect ratio (HAR) interconnect is a composite interconnect comprising:
a first conductive core; and
a first conductive layer that at least partially encapsulates the first conductive core.

14. The device of claim 13, wherein the first conductive layer is a diffusion barrier.

15. The device of claim 11, wherein the package further comprises a second high aspect ratio (HAR) interconnect, wherein a pitch between the first high aspect ratio (HAR) interconnect and the second high aspect ratio (HAR) interconnect is about 300 microns (μm) or less.

16. The device of claim 11, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in a automotive vehicle, and further including the device.

17. A method for fabricating a package, comprising:
providing a die;
forming a redistribution portion over the die;
forming a first solder interconnect over the redistribution portion; and
using the first solder interconnect to couple a first high aspect ratio (HAR) interconnect to the redistribution portion of the package, wherein the first high aspect ratio (HAR) interconnect comprises a width to height ratio of about at least 1:2.

18. The method of claim 17, wherein coupling the first high aspect ratio (HAR) interconnect comprises forming a composite interconnect and coupling the composite interconnect to the redistribution portion of the package, where forming the composite interconnect comprises:
forming a first conductive core; and
forming a first conductive layer that at least partially encapsulates the first conductive core.

19. The method of claim 18, wherein the first conductive layer is a diffusion barrier.

20. The method of claim 17, further comprising:
forming a second solder interconnect over the redistribution portion; and
using the second solder interconnect to couple a second high aspect ratio (HAR) interconnect to the redistribution portion of the package, wherein a pitch between the first high aspect ratio (HAR) interconnect and the second high aspect ratio (HAR) interconnect is about 300 microns (μm) or less.

21. A package comprising:
a die;
a plurality of solder balls coupled to the die;
a package substrate coupled to the die through the plurality of solder balls;
a first high aspect ratio (HAR) interconnect coupled to the package substrate, wherein the first high aspect ratio (HAR) interconnect comprises a width to height ratio of about at least 1:2; and
a first solder interconnect coupled to the first high aspect ratio (HAR) interconnect and the package substrate.

22. The package of claim 21, wherein the first high aspect ratio (HAR) interconnect is a composite interconnect comprising:
a first conductive core; and
a first conductive layer that at least partially encapsulates the first conductive core.

23. The package of claim 22, wherein the first conductive layer is a diffusion barrier.

24. The package of claim 22, wherein the composite interconnect further comprises a second conductive layer that at least partially encapsulates the first conductive layer.

25. The package of claim 22, wherein the first conductive core comprises a first surface, a second surface and a third surface, wherein the first conductive layer at least partially encapsulates the first surface, the second surface and the third surface of the first conductive core.

26. The package of claim 21, wherein the package is coupled to a printed circuit board (PCB) through the first high aspect ratio (HAR) interconnect.

27. The package of claim 21, further comprising a second high aspect ratio (HAR) interconnect, wherein a pitch between the first high aspect ratio (HAR) interconnect and the second high aspect ratio (HAR) interconnect is about 300 microns (μm) or less.

28. The package of claim 21, wherein the package is a chip scale package (CSP).

29. The package of claim 21, further comprising an encapsulation layer that at least partially encapsulates the die.

30. The package of claim 21, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in a automotive vehicle, and further including the device.
